(19) United States
(12) Patent Application Publication
(10) Pub. No.: US 2025/0153232 A1
(43) Pub. Date: May 15, 2025

(54) SPECIAL-SHAPED PART MACHINING MOLD AND DESIGN AND ASSEMBLY METHODS THEREOF

(71) Applicant: Shanghai Dianji University, Shanghai (CN)

(72) Inventors: Xiao XU, Shanghai (CN); Xin WANG, Shanghai (CN); Pan GONG, Shanghai (CN); Zhao LIU, Shanghai (CN); Jinhua HU, Shanghai (CN); Peng LIU, Shanghai (CN); Jialiang LIU, Shanghai (CN); Xiaofeng ZHANG, Shanghai (CN)

(73) Assignee: Shanghai Dianji University, Shanghai (CN)

(21) Appl. No.: 18/840,500

(22) PCT Filed: Nov. 26, 2022
(86) PCT No.: PCT/CN2022/134532

§ 371 Date: Aug. 22, 2024

(30) Foreign Application Priority Data
Nov. 22, 2022 (CN) 202211463706.2

(51) Int. Cl. B21C 23/04; G01L 5/16

(52) U.S. Cl. CPC B21C 23/04; G01L 5/16

(57) ABSTRACT

The present invention relates to a special-shaped part machining mold and design and assembly methods thereof. The design method includes: constructing a multi-layer combined mold according to parameters required by special-shaped part machining; analyzing an equivalent stress distribution after the mold is assembled, selecting a part of equivalent stress evaluation points, and performing equivalent strength simulation to obtain a pressing sleeve ratio change curve circumferentially distributed at a matching surface of the mold; obtaining curve changes at different positions in a circumferential direction of the mold according to the pressing sleeve ratio change curve circumferentially distributed at the matching surface of the mold, so that a new mold is designed; determining whether the new mold has a condition of uneven stress distribution or not; if yes, repeatedly analyzing equivalent stress distribution after the mold is assembled; and if not, completing the design of the mold.

### TECHNICAL FIELD

The present application relates to the field of mold designs, and more particularly, to a special-shaped part machining mold and design and assembly methods thereof.

### DESCRIPTION OF RELATED ART

At present, there are more and more demands for special-shaped part products with complex structures in the market, which are especially widely applied in aerospace devices, automotive covering parts, household appliance components and other fields.

A cold forging technology is a common method for the production of special-shaped part products. A plastic forming process of the products is completed under the condition of three-way compressive stress, so that a shape of the obtained forged part is close to a part forming shape, without any burr or less burrs. A material utilization ratio of some products can reach more than 95%, which greatly reduces the material cost; and even the materials can be directly used subsequently without machining. This forging method can not only save raw materials, but also greatly improve the internal quality and forming accuracy of the product, and the formed parts are stable in size and good in consistency.

In the actual production of precision cold forging, a multi-layer nested extrusion mold is generally used for special-shaped parts, and the mold generally has a regularly round shape. However, due to a large and asymmetrical forming force, there are often uneven stress distribution and even local stress concentration problems in a circumferential direction of the extrusion mold, resulting in serious wear and even local cracking between molds, thereby greatly shortening the service life of the mold. For example, in an extrusion process of a black metal special-shaped part, due to a considerable extrusion force per unit, the stress concentration and the tangential tensile stress inside a cavity of the special-shaped mold are large, which makes the mold prone to local wear and longitudinal cracking.

### SUMMARY OF THE INVENTION

Based on this, it is necessary to provide a special-shaped part machining mold and design and assembly methods thereof in view of the above technical problems, which can effectively solve the problem that a circumferential stress distribution at a matching surface of the mold is uneven, such that the mold has longer service life.

The first aspect of the present invention provides a design method of a special-shaped part machining mold, the method comprising:
constructing a multi-layer combined mold according to parameters required by special-shaped part machining;
analyzing an equivalent stress distribution after the mold is assembled, selecting a part of equivalent stress evaluation points, and performing equivalent strength simulation to obtain a pressing sleeve ratio change curve circumferentially distributed at a matching surface of the mold;
obtaining curve changes at different positions in a circumferential direction of the mold according to the pressing sleeve ratio change curve circumferentially distributed at the matching surface of the mold, so that a new mold is designed;
determining whether the new mold has a condition of uneven stress distribution or not; if yes, repeatedly
analyzing the equivalent stress distribution after the mold is assembled; and if not,
completing the design of the mold.

In one embodiment, the parameters required by special-shaped part machining comprises:
a shape and a material of a special-shaped part, and a magnitude of a desired molding force.

In one embodiment, prior to analyzing the equivalent stress distribution after the mold is assembled, the method further comprising:
adjusting an axial pressing sleeve ratio at each matching surface of the mold, so that the pressing sleeve ratio at the matching surface of the mold gradually increases or decreases in an axial direction, such that an axial pressing sleeve ratio at the adjacent matching surface of the mold changes in an opposite direction.

In one embodiment, the selecting a part of equivalent stress evaluation points comprises:
performing intensive point selection for a stress concentration position by using an uneven evaluation point selection method, and performing sparse and symmetrical point selection for other positions.

In one embodiment, performing the equivalent strength simulation comprises:
finely tuning a diameter of the mold at each evaluation point, and changing the sleeve pressing ratio at the matching surface of the mold, so as to adjust the equivalent stress distribution at the matching surface of the mold.

In one embodiment, prior to obtaining the pressing sleeve ratio change curve circumferentially distributed at the matching surface of the mold, the method further comprising:
performing repeated iteration on analysis of the equivalent stress distribution, evaluation point selection and equivalent stress distribution adjustment process.

In one embodiment, the designing the new mold comprises:
performing local micro-modification on a peripheral profile of a mold core to obtain a mold core that is not completely regularly round.

The second aspect of the present invention provides a special-shaped part machining mold, which is obtained by applying the design method as above, the mold comprises:
a mold core, which has a mold cavity inside that matches a profile of a special-shaped part to be machined;
an intermediate sleeve, which sleeves an outer ring of the mold core, wherein a profile of the matching surface between the intermediate sleeve and the mold core is not completely regularly round; and
an outer sleeve, which sleeves an outer ring of the intermediate sleeve, wherein an equivalent stress distribution at the matching surface among the outer sleeve, the intermediate sleeve and the mold core is uniform.

In one embodiment, a pressing sleeve ratio at one matching surface among the mold core, the intermediate sleeve and the outer sleeve gradually increases or decreases in an axial direction, and an axial pressing sleeve ratio at the other matching surface changes in an opposite direction.

The third aspect of the present invention provides an assembly method of a special-shaped part machining mold, which is applied to the mold mentioned above, wherein the method comprises:
assembling the mold core, the intermediate sleeve and the outer sleeve from inside to outside or from outside to inside by using a hot-sleeving method or a cold compression sleeving method.

According to the special-shaped part machining mold and the design and assembly methods thereof, by analyzing an equivalent stress distribution after the mold is assembled and finely tuning a profile at a matching surface according to the equivalent stress distribution, the equivalent stress distribution at the matching surface of the mold changes. This method has strong operability, low cost and high efficiency, and is suitable for the local stress adjustment of all cold forging molds for special-shaped parts and the optimal design and production of any precision forging extrusion molds. The local stress concentration in the subsequent use of the mold can be effectively reduced, and the shear stress on the mold in the process of cold forging deformation is offset to a certain extent, such that the stress concentration and breakage are avoided, and the problem that the circumferential stress distribution at the matching surface of the mold is uneven is improved, so the mold has longer service life.

### DESCRIPTION OF THE DRAWINGS

FIG. 1 is a diagram of steps of a design method of a special-shaped part machining mold in an embodiment;

FIG. 2 is a diagram of steps of a design method of a special-shaped part machining mold in another embodiment;

FIG. 3 is an equivalent stress distribution diagram before numerical simulation analysis for a special-shaped part machining mold in an embodiment;

FIG. 4 is an equivalent stress distribution diagram after numerical simulation analysis for a special-shaped part machining mold in an embodiment;

FIG. 5 is a schematic structural diagram of a fork-shaped part in an embodiment;

FIG. 6 is schematic structural diagram of a special-shaped part machining mold in an embodiment; and

FIG. 7 is a schematic structural diagram of a special-shaped part machining mold with an approximate circumferential curve after matching surface compensation in an embodiment.

In drawings, reference symbols represent the following components: 110—mold core; 120—intermediate sleeve; and 130—outer sleeve.

### DETAILED DESCRIPTION OF EMBODIMENTS

In order to make the objectives, the technical solutions and the advantages of the embodiments of the present application more clear, the technical solutions in the embodiments of the present application will be illustrated clearly and completely hereinafter with reference to the accompanying drawings in the embodiments of the present application. Apparently, the embodiments described are merely some but not all of the embodiments of the present application. Based on the embodiments of the present application, all other embodiments obtained by those of ordinary skills in the art without going through any creative work should fall within the scope of protection of the present application.

It should be noted that when an assembly is referred to as being “fixed to” or “arranged on” another assembly, it may be directly located on the other assembly, or an intermediate assembly may also exist. When an assembly is referred to as being “connected to” another assembly, it may be directly connected to the other assembly, or an intermediate assembly exists at the same time. The terms “vertical”, “horizontal”, “upper”, “lower”, “left”, “right” and similar expressions used in the description of the present application are for the purpose of illustration, but are not intended to be the sole embodiment.

Moreover, the terms “first” and “second” are used for descriptive purposes only and cannot be understood as indicating or implying relative importance, or implicitly indicating the number of technical features indicated thereby. Therefore, the feature defined by “first” and “second” may explicitly or implicitly include one or more of the features. In the description of the present invention, the meaning of “multiple” is two or more than two, unless otherwise specifically defined.

In the present application, unless otherwise definitely specified and limited, a first feature being provided “above” or “below” a second feature may mean that the first feature is in direct contact with the second feature, or indirectly in contact with the second feature via an intermediation. Moreover, the first feature being provided “over”, “above”, and “on” the second feature may mean that the first feature is provided directly above or diagonally above the second feature, or merely means that a horizontal height of the first feature is higher than that of the second feature. The first feature being provided “under”, “below”, and “beneath” the second feature may mean that the first feature is provided directly below or diagonally below the second feature, or merely means that a horizontal height of the first feature is lower than that of the second feature.

Unless otherwise defined, all technical and scientific terms used in the description of the present application have the same meaning as commonly understood by a person of ordinary skill in the art. The terms used in the description of the present application herein are only for the purpose of describing specific embodiments, and are not intended to limit the present application. The term “and/or” as used in the description of the present application includes any and all combinations of one or more related listed items.

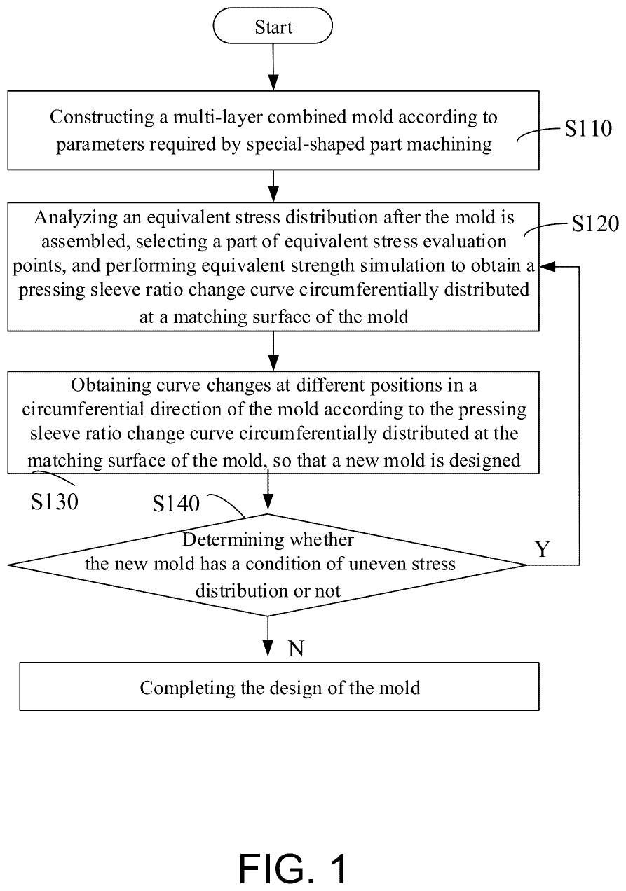

As shown in FIG. 1, in one embodiment, a design method of a special-shaped part machining mold includes the following steps:

In step S110, a multi-layer combined mold is constructed according to parameters required by special-shaped part machining.

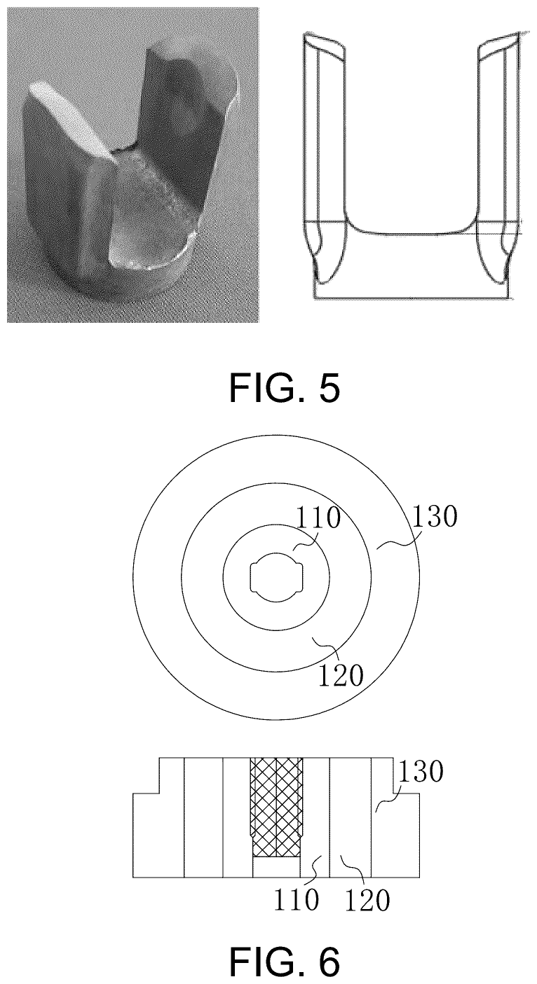

Specifically, the parameters required by special-shaped part machining includes a shape and a material of the special-shaped part, and a magnitude of a desired molding force. Taking a currently existing fork-shaped part shown in FIG. 5 as an example, in actual production, this part is formed by cold extrusion, with a huge and uneven forming force. The stress concentration at the edge of the inner corner of the mold easily occurs, which causes cracking and short life of the mold in cold extrusion. A material selected for the fork-shaped part is 20 Cr (low carburizing steel), and a blank model is imported into molding software for numerical simulation analysis. A maximum load of the material in the deformation process may be obtained to be about 2.06*106 N. According to the magnitude of the molding force of the fork-shaped part, molding equipment with a tonnage of 300 T is selected. According to the material of the fork-shaped part, a multi-layer combined mold is constructed. The multi-layer combined mold includes three layers of a mold core, an intermediate sleeve and an outer sleeve, wherein the mold core of the mold is made of a Japanese DIJET superhard NC16/NC14 tungsten steel plate material, and the intermediate sleeve and the outer sleeve are made of H13 mold steel or a SKD61 material.

In step S120, an equivalent stress distribution after the mold is assembled is analyzed, a part of equivalent stress evaluation points are selected, and equivalent strength simulation is performed to obtain a pressing sleeve ratio change curve circumferentially distributed at a matching surface of the mold.

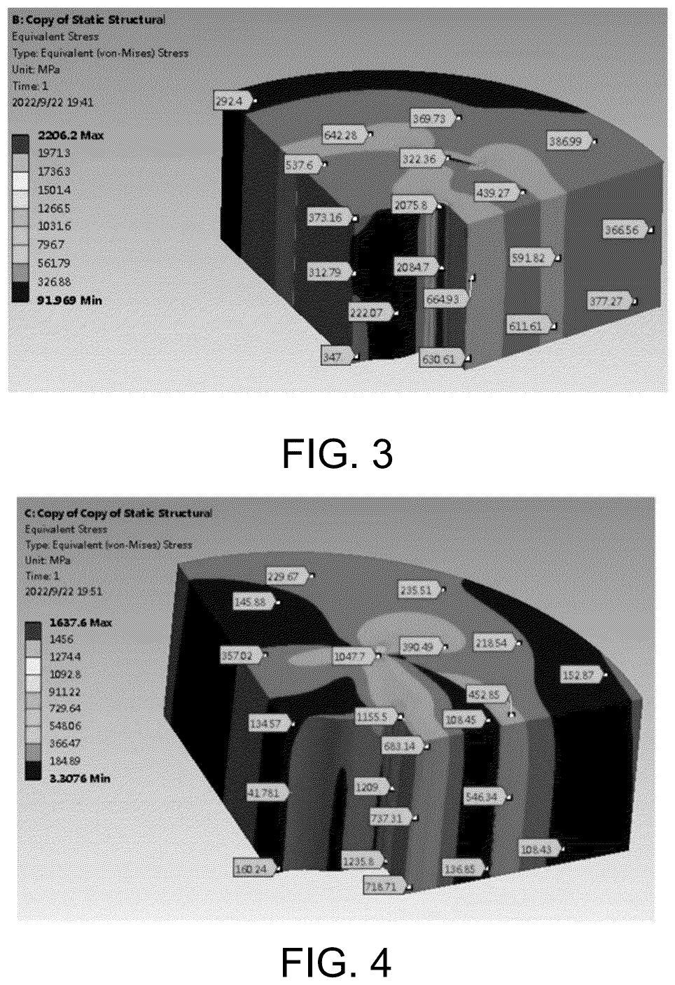

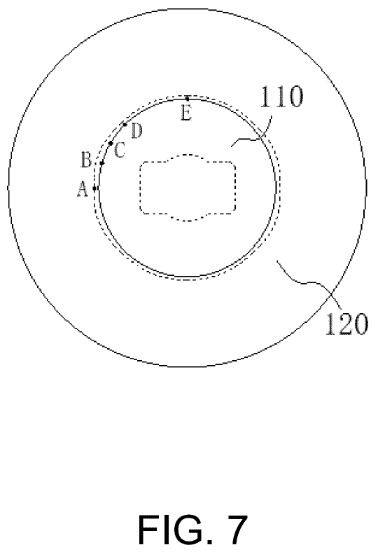

Specifically, according to a principle of machined mold size and assembly sequence, a finite element analysis model is established to analyze a preload distribution after mold assembly. For example, numerical simulation software such as deform/ANSYS/forge is used to analyze a stress-strain distribution between various layers of the mold. As shown in FIG. 3, the stress distribution inside the mold core and at the matching surface between the outer sleeve and the intermediate sleeve under a combined condition of a conventional circle-to-circle interference fit of 0.6%. It can be seen from FIG. 3 that there is an obvious stress set at the corner of the mold (corresponding to an edge position outside the fork-shaped part) at this time, and a maximum equivalent stress is about 2075 MPa. At this time, several stress evaluation points are selected, and a circular diameter at each selected point is finely-tuned, so as to adjust a pressing sleeve ratio at each selected point to change the equivalent stress distribution in the circumferential direction of the mold, and finally a pressing sleeve ratio (pressing sleeve ratio=interference/matching diameter) change curve distributed along the circumference on the matching surface in an ideal state is obtained, as shown in FIG. 7. It should be noted that, in the figure, a dashed line represents the mold core, and a solid line represents a profile shape of the intermediate sleeve. In order to emphasize the design of the pressing sleeve ratio curve, the shape and size of the dashed line are moderately “enlarged” and “exaggerated”. An actual profile curve of the mold core is made with a small number of modifications and deletions on the basis of a regularly round shape.

In step S130, curve changes at different positions in a circumferential direction of the mold are obtained according to the pressing sleeve ratio change curve circumferentially distributed at the matching surface of the mold, so that a new mold is designed.

Specifically, a circumferential curve change of the mold is calculated according to the pressing sleeve ratio change curve, and a mold core model is reconstructed based on this change, so the round mold core shape is no longer so regular.

In step S140, whether the new mold has a condition of uneven stress distribution or not is determined; if yes, the step S120 is performed repeatedly; and if not, the design of the mold is completed.

Specifically, according to a new mold size and assembly sequence, a finite element analysis model is established to analyze a preload distribution after mold assembly. As shown in FIG. 4, the stress distribution of the mold that is re-simulated according to an approximate circumferential curve design after the compensation of the above-mentioned matching surface is shown. At this time, a corner position inside the mold core is still a stress concentration position, and the equivalent stress is about 1155 MPa, which is about 44.3% lower than 2075 MPa. Therefore, if the uneven local stress distribution cannot be improved significantly, the equivalent stress distribution after mold assembly is repeatedly analyzed and the subsequent steps are performed.

According to the design method of the special-shaped part machining mold, by analyzing the equivalent stress distribution after the mold is assembled and finely tuning the profile at the matching surface according to the equivalent stress distribution, the equivalent stress distribution at the matching surface of the mold changes. This method has strong operability, low cost and high efficiency, and is suitable for the local stress adjustment of all cold forging molds for special-shaped parts and the optimal design and production of any precision forging extrusion molds. The local stress concentration in the subsequent use of the mold can be effectively reduced, and the shear stress on the mold in the process of cold forging deformation is offset to a certain extent, so the stress concentration and breakage are avoided, and the problem that the circumferential stress distribution at the matching surface of the mold is uneven is improved, so the mold has longer service life.

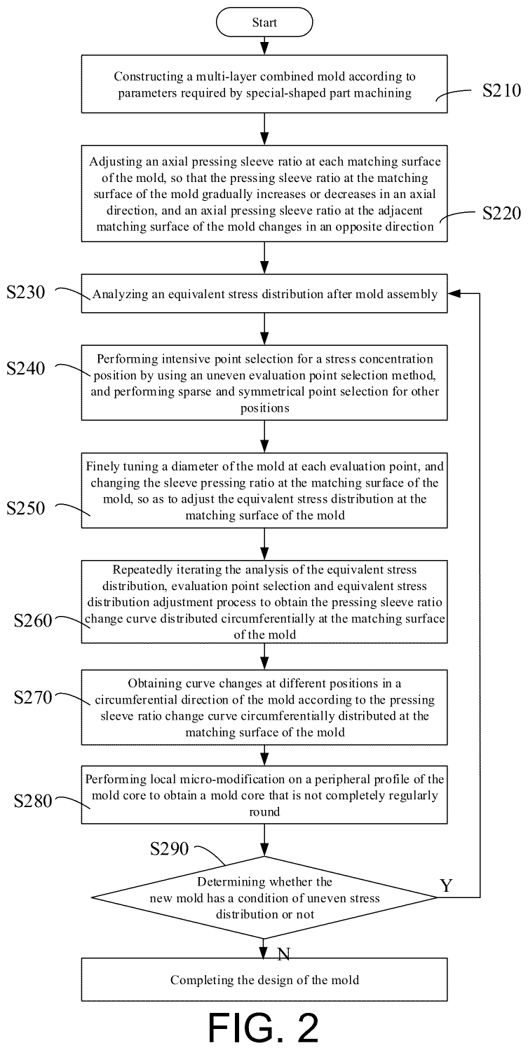

As shown in FIG. 2, in an embodiment, a design method of a special-shaped part machining mold comprises the following steps:

In step S210, a multi-layer combined mold is constructed according to parameters required by special-shaped part machining.

Specifically, the parameters required by special-shaped part machining include a shape and a material of the special-shaped part, and a magnitude of a desired molding force. Taking a currently existing fork-shaped part shown in FIG. 5 as an example, in actual production, this part is formed by cold extrusion, with a huge and uneven forming force. The stress concentration at the edge of the inner corner of the mold easily occurs, which causes cracking and short life of the mold in cold extrusion. A material selected for the fork-shaped part is 20 Cr (low carburizing steel), and a blank model is imported into molding software for numerical simulation analysis, that is, a maximum load of the material in the deformation process may be obtained to be about 2.06*106 N. According to the magnitude of the molding force of the fork-shaped part, molding equipment with a tonnage of 300 T is selected. According to the material of the fork-shaped part, a multi-layer combined mold is constructed. The multi-layer combined mold includes three layers of a mold core, an intermediate sleeve and an outer sleeve, wherein the mold core of the mold is made of a Japanese DIJET superhard NC16/NC14 tungsten steel plate material, and the intermediate sleeve and the outer sleeve are made of H13 mold steel or a SKD61 material.

In step S220, an axial pressing sleeve ratio (pressing sleeve ratio=interference/matching diameter) at each matching surface of the mold is adjusted, so that the pressing sleeve ratio at the matching surface of the mold gradually increases or decreases in an axial direction, and an axial pressing sleeve ratio at the adjacent matching surface changes in an opposite direction.

Specifically, it has been found from researches and production practices in recent years that an assembly method of a prestressed mold has a great influence on the life of the mold, and the distribution of a preload force of the mold in an axial direction is uneven. Generally speaking, there is an end effect in a multi-layer nested extrusion mold, that is, the preload force is maximum in the middle and gradually decreases at both ends in the axial direction. If the traditional heat-sleeving method with upper and lower pressing sleeve ratios being consistent is used during assembly, the mold itself will produce a certain amount of bending stress, and the shear stress on the mold during the extrusion process will also have a high probability of causing mold cracking.

Therefore, the principle of complementarity is used here to finely tune an axially changed pressing sleeve ratio between various layers of the mold. That is, an interference fit amount at the matching surface of the mold is finely tuned in an axial direction, wherein one selects “loose in upper part and tight in lower part”, and the other selects “tight in upper part and loose in lower part”. By adjusting the prestress of the mold with this method of changing the axially changed pressing sleeve ratio, the bending stress generated inside the mold itself can be reduced or even eliminated, and the shear stress on the mold in the extrusion process can also be offset to a certain extent, so as to avoid the stress concentration and cracking of the mold, thereby greatly reducing the possibility of mold cracking.

In step S230, an equivalent stress distribution after the mold is assembled is analyzed. Specifically, according to a principle of machined mold size and assembly sequence, a finite element analysis model is established to analyze a preload distribution after mold assembly. For example, numerical simulation software such as deform/ANSYS/forge is used to analyze a stress-strain distribution between various layers of the mold. As shown in FIG. 3, the stress distribution inside the mold core and at the matching surface between the outer sleeve and the intermediate sleeve under a combined condition of a conventional circle-to-circle interference fit of 0.6% is shown. It can be seen from the figure that there is an obvious stress set at the corner of the mold (corresponding to an edge position outside the fork-shaped part) at this time, and a maximum equivalent stress is about 2075 MPa.

In step S240, an uneven evaluation point selection method is used to perform intensive point selection for a stress concentration position, and sparse and symmetrical point selection for other positions.

Specifically, according to the stress distribution, different evaluation point selection methods are adopted to perform intensive point selection for the stress concentration position, and sparse and symmetrical point selection for other positions. According to these evaluation point selection methods, the evaluation points A, B, C, D, and E in FIG. 7 are finally obtained.

In step S250, a diameter of the mold at each evaluation point is finely tuned, and the sleeve pressing ratio at the matching surface of the mold is changed, so as to adjust the equivalent stress distribution at the matching surface of the mold.

Specifically, by finely tuning the circular diameter at the selected point, the pressing sleeve ratio at each point is adjusted to change the equivalent stress distribution of the mold in the circumferential direction, so as to improve the consumption of the mold.

In step S260, analysis of the equivalent stress distribution, evaluation point selection and equivalent stress distribution adjustment process are repeatedly iterated to obtain the pressing sleeve ratio change curve distributed circumferentially at the matching surface of the mold.

Specifically, by the repeated iteration of the analysis of the equivalent stress distribution, evaluation point selection and equivalent stress distribution adjustment process to continuously adjust the profile at the matching surface of the mold, the stress concentration at the matching surface of the mold is continuously improved, and finally the pressing sleeve ratio change curve distributed along the circumference of the matching surface under an ideal state is obtained, as shown in FIG. 7. It should be noted that, in the figure, a dashed line represents the mold core, and a solid line represents a profile shape of the intermediate sleeve. In order to emphasize the design of the pressing sleeve curve, the shape and size of the dashed line are moderately “enlarged” and “exaggerated”. An actual profile curve of the mold core is made with a small number of modifications and deletions on the basis of a regular round shape.

In step S270, curve changes at different positions in a circumferential direction of the mold are obtained according to the pressing sleeve ratio change curve circumferentially distributed at the matching surface of the mold.

Specifically, according to the pressing sleeve ratio change curve, by taking a profile of an original matching surface of the mold as a reference, a curve change of the mold in the circumferential direction can be calculated, and the mold with the compensated matching surface can be obtained by combining the curve change with the profile of the original matching surface of the mold.

In step S280, local micro-modification is performed on a peripheral profile of the mold core to obtain a mold core that is not completely regularly round. The intermediate sleeve and the outer sleeve are combined to obtain a new mold with the compensated matching surface.

Specifically, the curve shapes of the mold at different positions and the “increment and decrement” of fine-tuning of the mold shape are backstepped according to the pressing sleeve ratio curve, and the extrusion mold shape that is not completely regularly round is determined.

In step S290, whether the new mold has a condition of uneven stress distribution or not is determined; if yes, the step S230 is performed repeatedly; and if not, the design of the mold is completed.

Specifically, according to a new mold size and assembly sequence, a finite element analysis model is established to analyze a preload distribution after mold assembly. As shown in FIG. 4, the stress distribution of the mold that is re-simulated according to an approximate circumferential curve design after the compensation of the above-mentioned matching surface is shown. At this time, a corner position inside the mold core is still a stress concentration position, and the equivalent stress is about 1155 MPa, which is about 44.3% lower than 2075 MPa. Therefore, if the uneven local stress distribution cannot be improved significantly, the equivalent stress distribution after mold assembly is repeatedly analyzed and the subsequent steps are performed.

According to the design method of the special-shaped part machining mold, by changing the axial pressing sleeve ratio at the matching surface of the mold, the axial pressing sleeve ratios at two adjacent matching surfaces of the mold are set in opposite directions, such that the bending stress generated inside the mold itself can be reduced or even eliminated, and the shear stress on the mold in the extrusion process can also be offset to a certain extent, so as to avoid the stress concentration and breakage of the mold, thereby greatly reducing the possibility of mold cracking. By analyzing the equivalent stress distribution after the mold is assembled and finely tuning the profile at the matching surface according to the equivalent stress distribution, the equivalent stress distribution at the matching surface of the mold changes. This method has strong operability, low cost and high efficiency, and is suitable for the local stress adjustment of all cold forging molds for special-shaped parts and the optimal design and production of any precision forging extrusion molds. The local stress concentration in the subsequent use of the mold can be effectively reduced, and the shear stress on the mold in the process of cold forging deformation is offset to a certain extent, such that the stress concentration and breakage are avoided, and the problem that the circumferential stress distribution at the matching surface of the mold is uneven is improved, so the mold has longer service life.

As shown in FIG. 6, in one embodiment, a special-shaped part machining mold is obtained by applying the design method of the above-mentioned special-shaped part machining mold. The special-shaped part machining mold includes a mold core 110, an intermediate sleeve 120 and an outer sleeve 130. The mold core 110 has a mold cavity inside that matches a profile of a special-shaped part to be machined. The intermediate sleeve 120 sleeves an outer ring of the mold core 110, and a profile of the matching surface between the intermediate sleeve 120 and the mold core 110 is not completely regularly round. The outer sleeve 130 sleeves an outer ring of the intermediate sleeve 120, wherein an equivalent stress distribution at the matching surface among the outer sleeve 130, the intermediate sleeve 120 and the mold core 110 is uniform. According to the special-shaped part machining mold, the equivalent stress distribution at the matching surface among the outer sleeve 130, the intermediate sleeve 120 and the mold core 110 is uniform, and the service life is longer.

In one embodiment, a pressing sleeve ratio at one matching surface among the mold core 110, the intermediate sleeve 120 and the outer sleeve 130 gradually increases or decreases in an axial direction, and an axial pressing sleeve ratio at the other matching surface changes in an opposite direction.

Specifically, it has been found from researches and production practices in recent years that the assembly method of the prestressed mold has a great influence on the life of the mold, and the distribution of a preload force of the mold in an axial direction is uneven. Generally speaking, there is an end effect in a multi-layer nested extrusion mold, that is, the preload force is maximum in the middle and gradually decreases at both ends in the axial direction. If the traditional heat-sleeving method with upper and lower pressing sleeve ratios being consistent is used during assembly, the mold itself will produce a certain amount of bending stress, and the shear stress on the mold during the extrusion process will also have a high probability of causing mold cracking.

Therefore, the principle of complementarity is used here to finely tune an axially changed pressing sleeve ratio between various layers of the mold. That is, an interference fit amount at the matching surface of the mold is finely tuned in an axial direction, wherein one selects “loose in upper part and tight in lower part”, and the other selects “tight in upper part and loose in lower part”. By adjusting the prestress of the mold with this method of changing the axially changed pressing sleeve ratio, the bending stress generated inside the mold itself can be reduced or even eliminated, and the shear stress on the mold in the extrusion process can also be offset to a certain extent, so as to avoid the stress concentration and breakage of the mold, thereby greatly reducing the possibility of mold cracking.

Still for the fork-shaped part in FIG. 5, a conventional regular mold with the circular mold core 110 is designed here. The overall circumferentially and axially changed pressing sleeve ratios of the mold are consistent with those of the content in the above embodiments, and the circumferentially changed pressing sleeve ratio of the mold is changed without numerical analysis. That is, the interference fit amount between the mold core 110 and the intermediate sleeve 120 is set to 0.6%. Through the actual production test, it is known that the life of the conventional mold is about 20,000 times, while the life of the mold in the present embodiment is about 50,000 times, so the life of the mold is increased by about 150%, thereby effectively prolonging the life of the mold and reducing the production cost.

In one embodiment, according to the assembly method of the special-shaped part machining mold, the mold core, the intermediate sleeve and the outer sleeve are assembled from inside to outside or from outside to inside by using a hot-sleeving method or a cold compression sleeving method.

Specifically, the size of the outermost mold is determined first according to a tonnage model of molding equipment, and then the diameters of other molds are determined in turn according to the strength requirements for each layer of mold. In addition, a pressing sleeve sequence is generally as follows: the stipulated extrusion molds are, from an outermost layer to an innermost layer, named as an outermost mold, a penultimate mold, and a third-to-last mold . . . up to an innermost mold. During assembly, specifically, the penultimate mold is pressed into an outermost layer, the third-to-last mold is pressed into a penultimate layer, a fourth-to-last mold is pressed into a third-to-last layer . . . and so on, all of which are assembled finally by using a hot-sleeving method. This order is reversed in the cold compression sleeving method.

Various technical features of the foregoing embodiments may be randomly combined. To make description concise, not all possible combinations of the technical features in the foregoing embodiments are described. However, the combinations of these technical features shall be considered as falling within the scope recorded by this description provided that no conflict exists.

The foregoing embodiments only describe several implementations of the present application, which are described specifically and in detail, but cannot be construed as a limitation to the patent scope of the present application. It should be noted that for a person of ordinary skill in the art, several transformations and improvements can be made without departing from the idea of the present application. These transformations and improvements belong to the protection scope of the present application. Therefore, the protection scope of the patent of the present application shall be subject to the appended claims.

1. A design method of a special-shaped part machining mold, the design method comprising:
constructing a multi-layer combined mold according to parameters required by special-shaped part machining;
analyzing an equivalent stress distribution after the mold is assembled, selecting a part of equivalent stress evaluation points, and performing equivalent strength simulation to obtain a pressing sleeve ratio change curve circumferentially distributed at a matching surface of the mold;
obtaining curve changes at different positions in a circumferential direction of the mold according to the pressing sleeve ratio change curve circumferentially distributed at the matching surface of the mold, so that a new mold is designed;
determining whether the new mold has a condition of uneven stress distribution or not; if yes, repeatedly analyzing the equivalent stress distribution after the mold is assembled; and if not, completing a design of the mold.

2. The design method of the special-shaped part machining mold according to claim 1, wherein the parameters required by special-shaped part machining comprises:
a shape of a special-shaped part and a material of the special-shaped part, and a magnitude of a desired molding force.

3. The design method of the special-shaped part machining mold according to claim 1, prior to analyzing the equivalent stress distribution after the mold is assembled, the design method further comprising:
adjusting an axial pressing sleeve ratio at each of the matching surface of the mold, so that the pressing sleeve ratio at the matching surface of the mold gradually increases or decreases in an axial direction, such that an axial pressing sleeve ratio at the adjacent matching surface of the mold changes in an opposite direction.

4. The design method of the special-shaped part machining mold according to claim 3, wherein the selecting the part of equivalent stress evaluation points comprises:
performing intensive point selection for a stress concentration position by using an uneven evaluation point selection method, and performing sparse and symmetrical point selection for other positions.

5. The design method of the special-shaped part machining mold according to claim 4, wherein performing the equivalent strength simulation comprises:
finely tuning a diameter of the mold at each of the equivalent stress evaluation points, and changing the pressing sleeve ratio at the matching surface of the mold, so as to adjust the equivalent stress distribution at the matching surface of the mold.

6. The design method of the special-shaped part machining mold according to claim 5, prior to obtaining the pressing sleeve ratio change curve circumferentially distributed at the matching surface of the mold, the design method further comprising:
performing repeated iteration on analysis of the equivalent stress distribution, evaluation point selection and equivalent stress distribution adjustment process.

7. The design method of the special-shaped part machining mold according to claim 6, wherein the designing the new mold comprises:
performing local micro-modification on a peripheral profile of a mold core to obtain a mold core that is not completely regularly round.

8. The special-shaped part machining mold, which is obtained by applying the design method according to claim 1, wherein the mold comprises:
a mold core, which has a mold cavity inside that matches a profile of a special-shaped part to be machined;
an intermediate sleeve, which sleeves an outer ring of the mold core, wherein a profile of a matching surface between the intermediate sleeve and the mold core is not completely regularly round; and
an outer sleeve, which sleeves an outer ring of the intermediate sleeve, wherein an equivalent stress distribution at a matching surface among the outer sleeve, the intermediate sleeve and the mold core is uniform.

9. The special-shaped part machining mold according to claim 8, wherein a pressing sleeve ratio at one matching surface among the mold core, the intermediate sleeve and the outer sleeve gradually increases or decreases in an axial direction, and an axial pressing sleeve ratio at the other matching surface changes in an opposite direction.

10. An assembly method of a special-shaped part machining mold,
which is applied to the mold according to claim 8, wherein the method comprises:
assembling the mold core, the intermediate sleeve and the outer sleeve from inside to outside or from outside to inside by using a hot-sleeving method or a cold compression sleeving method.
